(19) United States
(12) Patent Application Publication
(10) Pub. No.: US 2009/0196717 A1
(43) Pub. Date: Aug. 6, 2009

(54) Apparatus for Handling a Substrate and a Method Thereof

(76) Inventor: Scott C. Holden, Melrose, MA (US)

Correspondence Address: Nields, Lemack & Frame, LLC, 176 E. MAIN STREET, SUITE 5, WESTBOROUGH, MA, 01581, US

(21) Appl. No.: 12/361,582

(22) Filed: Jan. 29, 2009

Related U.S. Application Data
(60) Provisional application No. 61/025,142, filed on Jan. 31, 2008.

(51) Int. Cl. H01L 21/677; B25J 9/16; B25J 13/00; B25J 19/02

(52) U.S. Cl. 414/222.02; 414/816; 414/806; 901/9; 901/14; 901/46

(57) ABSTRACT

An apparatus and method of handling substrates is disclosed. A detecting system, capable of determining whether a substrate is tilted in relation to the platen, is positioned proximate to the substrate. In some embodiments, the detecting system is a distance measuring system. In other embodiments, it is an angle sensor. The detecting system is in communication with a controller, which, in turn, is in communication with a substrate handling robot. If, based on information received from the detecting system, the controller determines that the substrate is tilted beyond an acceptable range, it is assumed that the substrate has remained attached to the platen. In such a case, the substrate handling robot does not attempt to remove it from the platen. In this way, the substrate is not damaged.

This application claims priority of U.S. Provisional Patent Application Ser. No. 61/025,142, filed Jan. 31, 2008, the disclosure of which is hereby incorporated by reference.

### FIELD

This disclosure relates to a substrate handling, and more particularly to an apparatus and a method of handling a substrate.

### BACKGROUND

An electronic device may result from a substrate that has undergone various processes. One of the processes may include introducing impurities or dopants to alter one or more of electrical, optical, and mechanical properties of the original substrate. For example, charged ions, as impurities or dopants, may be introduced to a substrate, such as a silicon wafer, to alter electrical properties of the substrate. One of the processes that introduces impurities to the substrate may be an ion implantation process.

Among other tools, an ion implanter is used to perform ion implantation. A block diagram of a conventional ion implanter is shown in FIG. 1. The conventional ion implanter may comprise an ion source 102 that may be biased by a power supply 101. The ion source 102 is typically contained in a vacuum chamber known as a source housing (not shown). The ion implanter system 100 may also comprise a series of beam-line components through which ions 10 pass. The series of beam-line components may include, for example, extraction electrodes 104, a 90° magnet analyzer 106, a first deceleration (D1) stage 108, a 70° magnet collimator 110, and a second deceleration (D2) stage 112. Much like a series of optical lenses that manipulate a light beam, the beam-line components can manipulate and focus the ion beam 10 before steering it towards a substrate or wafer 114, which is disposed on a platen 116.

In operation, a substrate handling robot (not shown) disposes the substrate 114 on the platen 116 that can be moved in one or more dimensions (e.g., translate, rotate, and tilt) by an apparatus, sometimes referred to as a “roplat” (not shown). Meanwhile, ions are generated in the ion source 102 and extracted by the extraction electrodes 104. The extracted ions 10 travel in a beam-like state along the beam-line components and implanted on the substrate 114. After implanting ions is completed, the substrate handling robot may remove the substrate 114 from the platen 116 and from the ion implanter 100.

Referring to FIGS. 2A and 2B, there is shown a block diagram illustrating the platen 116 supporting the substrate 114 during the ion implantation process. As illustrated in FIG. 2A, the platen may comprise an edge 202 and a plurality of bumps 204 that are in contact with the substrate 114. In addition, the platen may also include at least one cooling region 206. During the implantation process, cooling gas may be provided to the cooling region 206 prevent the substrate 114 from overheating. The platen 116 may further include a plurality of lift pins 208 that may move so as to push the substrate 114 away from the platen 116. FIG. 3 is a top view of a platen 116 showing the position of the lift pins 208. Although this embodiment utilizes three lift pins, the disclosure is not limited to this embodiment.

Initially, the lift pins 208 are in a lowered position. The substrate handling robot 210 then moves a substrate to a position above the platen 116. The lift pins 208 may then be actuated to an elevated position (as shown ion FIG. 2A) and may receive the substrate 114 from the substrate handling robot 210. Thereafter, the substrate handling robot moves away from the platen 116 and the lift pins 208 may recede into the platen 116 such that the edge 202 and the bumps 204 of the platen 116 may be in contact with the substrate 114, as shown in FIG. 2B. The implantation process may then be performed with the lift pins 208 in this recessed position. After the implantation process, the substrate is unclamped from the platen, having been held in place, such as by electrostatic force. The lift pins 208 may then be extended into the elevated position, thereby elevating the substrate 114 and separating the substrate 114 from the edge 202 and the bumps 204 of the platen 116, as shown in FIG. 2A. The substrate handling robot 210 may then be disposed under the substrate 114, where it can retrieve the implanted substrate 114 at the elevated position. The lift pins 208 may then be lowered, and the robot 210 may then be actuated so as to remove the substrate 114 from the implanter.

One of the deficiencies of the conventional ion implanter 100 may be found in the process of removing the substrate 114 from the platen 116. During implantation, a portion of the substrate 114 may be in contact with the edge 202 of the platen 116. As the substrate 114 is elevated, the contacted portion may remain attached to the edge 202 of the platen 116, while other portions of the substrate may be elevated. The substrate handling robot 210 attempting to retrieve the substrate 114 may collide with the partially elevated substrate 114, and the substrate 114 may either break from the collision or fall to another portion of the implanter 100.

Since these collisions may decrease the efficiency of the implanter 100, the cost of processing the substrate 114, and ultimately the cost of the manufactured semiconductor devices, may increase. As such, a new apparatus and method for removing the implanted substrate 114 from the platen 116 is needed.

### SUMMARY

The problems of the prior art are overcome by the apparatus and method of this disclosure. An apparatus having a detecting system and controller and a substrate robot is used to handle processed substrates. The detecting system, capable of determining whether a substrate is tilted, is positioned proximate to the substrate. The detecting system is adapted to measure the tilt of the substrate relative to the platen. The detecting system is in communication with a controller, which, in turn, is in communication with a substrate handling robot.

In some embodiments, the detecting system is a distance measuring system. In this embodiment, the detecting system measures the distance to the substrate after the robot has placed the substrate on the platen. It then measures the distance to the substrate after the substrate is processed. If the difference between these two distances is too great, the controller determines that the substrate is tilted.

In other embodiments, the detecting system is an angle sensor. In this embodiment, the detecting system measures the difference in direction between the transmitted wave and the wave reflected off the substrate. If this difference is too great, the controller determines that the substrate is tilted.

If the controller, based on date received from the detecting system, determines that the substrate is tilted beyond an acceptable range, it is assumed that the substrate has remained attached to the platen. In such a scenario, the substrate handling robot does not attempt to remove it from the platen. By preventing the substrate handling robot from attempting to remove the substrate, the substrate is not damaged.

### BRIEF DESCRIPTION OF THE DRAWINGS

In order to facilitate a fuller understanding of the present disclosure, reference is now made to the accompanying drawings, in which like elements are referenced with like numerals. These drawings should not be construed as limiting the present disclosure, but are intended to be exemplary only.

FIG. 1 represents a traditional ion implantation system;

FIG. 2A represents a block diagram showing a platen supporting a substrate with the lift pins extended;

FIG. 2B represents a block diagram showing a platen supporting a substrate with the lift pins recessed;

FIG. 3 represents a top of a platen;

FIG. 4 represents a first embodiment of the apparatus, with the substrate in the correct position;

FIG. 5 represents a first embodiment of the apparatus, with the substrate in the tilted position; and

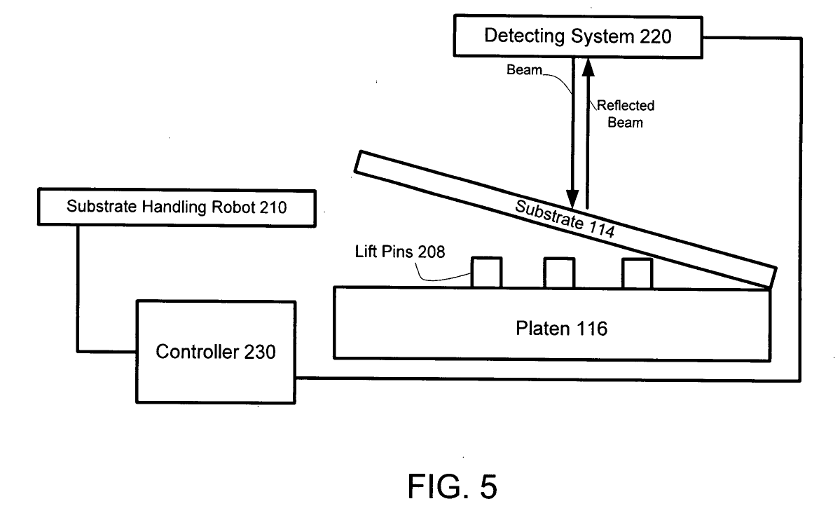

FIG. 6 represents a second embodiment of the apparatus, with the substrate in the tilted position.

### DETAILED DESCRIPTION

In the present disclosure, several embodiments of an apparatus and a method for handling a processed substrate are introduced. For purpose of clarity and simplicity, the present disclosure will focus on an apparatus and a method for handling a substrate that is processed by a beam-line ion implanter. Those skilled in the art, however, may recognize that the present disclosure is equally applicable to other types of processing systems including, for example, a plasma immersion ion implantation (“PIII”) system, a plasma doping (“PLAD”) system, an etching system, an optical based processing system, and a chemical vapor deposition (CVD) system. As such, the present disclosure is not to be limited in scope by the specific embodiments described herein.

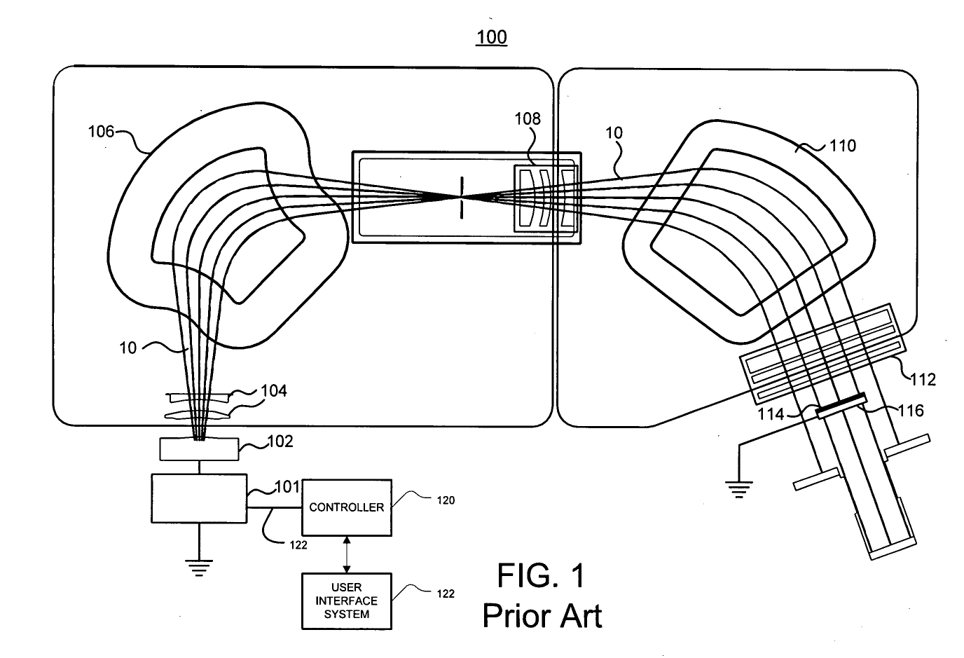

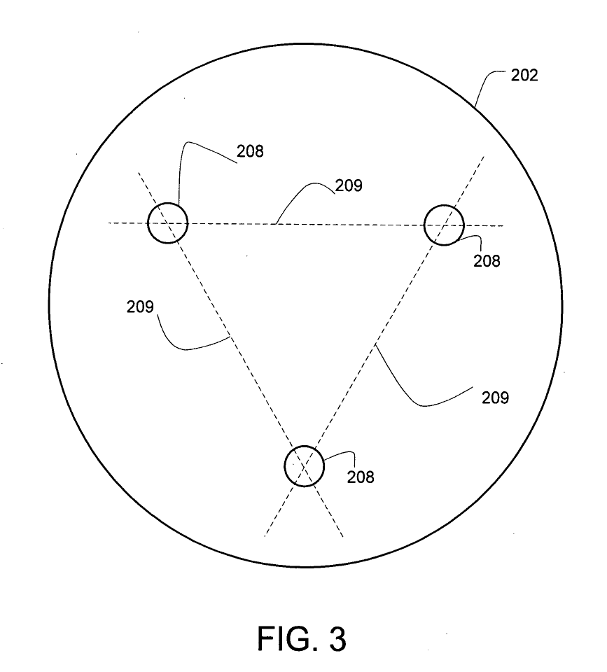

Referring to FIG. 3, there is shown a block diagram of an apparatus for handling a processed substrate, according to one embodiment of the present disclosure. In the present disclosure, the apparatus may be contained in an ion implanter similar to the one shown in FIG. 1. The apparatus may comprise at least one substrate orientation detecting system 220 and a controller 230 coupled to the at least one substrate orientation detecting system 220. Additionally, the controller 230 is coupled to a substrate handling robot 210. As illustrated in FIG. 3, the at least one detecting system 220 may be disposed proximate to the substrate 114. For example, the detecting system 220 may be disposed in front of the substrate, at a side of the substrate, or behind the substrate.

In one embodiment, the detecting system 220 is a distance measurement system, capable of determining the distance between the detecting system 220 and the substrate 114 or a specific portion of the substrate 114. In this embodiment, the detecting system 220 may preferably be an optical light based system, such as a laser based system comprising a light source and one or more light detectors, located proximate to the light source. The light source is used to illuminate the object to be measured. Once illuminated, the object reflects a portion of the light back toward the detecting system. The light detectors determine the angle of incidence of the reflected beam, using various techniques, including but not limited to cameras and focusing lenses. Based on the angle of incidence of the reflected beam, the detecting system can determine the distance to the object. Alternatively, the detecting system may utilize induction or ultrasonic waves to determine the distance to the object. The system may also be an electromagnetic wave based system.

Time of Flight systems determine the distance to an object based on the time required for light to travel to the object and back to the detecting system. In some embodiments, a periodic waveform, such as a sinusoidal wave is emitted from a laser. The phase difference between the emitted wave and reflected wave is used to determine the distance from the detecting system to the object. Other techniques capable of measuring the distance to an object are also within the scope of the disclosure.

The detecting system 220 may be configured to observe at least a portion of the substrate. Preferably, the observed portion may be near the center of the substrate 114 or near an outer edge of the substrate 114. However, it is also within the scope of the present disclosure that the detecting system may be configured to observe other portions of the substrate. Furthermore, the detecting system 220 may also be configured to observe, for example, platen or lift pins. In other embodiments, a plurality of detecting systems 220 is utilized to observe a plurality of locations. For example, detecting systems 220 may be used to measure a plurality of locations along the outer edge of the substrate 114. In this way, the detecting systems are able to reliably ascertain substrate adhesion issues.

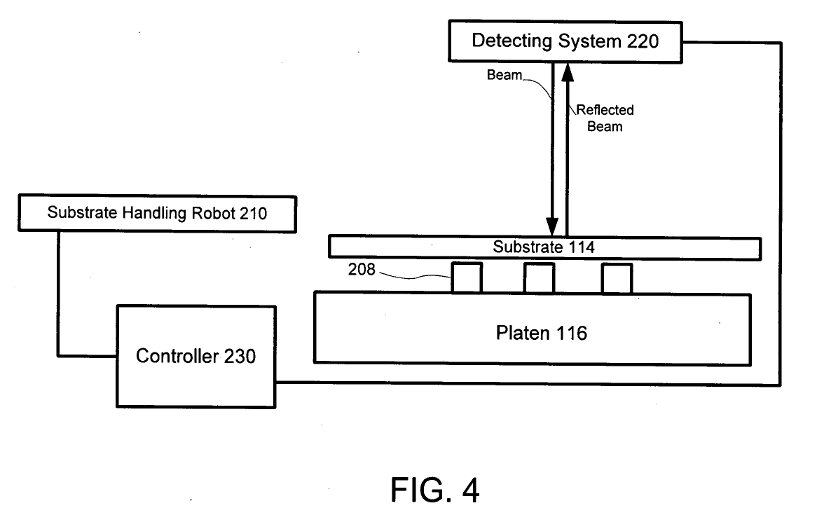

Hereinafter, operation of the distance based method for determining the orientation of the substrate 114 will be described. Initially, the substrate 114 is received by the lift pins 208, as shown in FIG. 4. The distance between at least a portion of the substrate 114 in the elevated state and the detecting system 220 is measured (the “first distance”). Thereafter, the substrate 114 is lowered and disposed on the platen 116, and the substrate 114 is processed. After being processed, the substrate 114 is raised to the elevated state by the lift pins 208 to be retrieved by the substrate handling robot 210.

Prior to being retrieved, however, the distance between the same portion of the substrate 114 and the detecting system 220 is measured for the second time (the “second distance”). Thereafter, the first and second distances are compared by the controller 230. If the difference of the first and second distances is unacceptably high (e.g. 1-10 mm), a determination can be made that at least a portion of the substrate 114 is attached to the platen 116 and the substrate 114 is oriented in an excessively tilted state. Thus, the controller 230 compares the difference between the first and second distances to an acceptable range. For example, the controller 230 may be configured such that the difference between the two distances must be in the range between −1 and +1 mm. If such a determination is made, the substrate handling robot 210 may be prevented from retrieving the substrate 114. Otherwise, the robot 210 may retrieve the substrate 114.

Alternatively, the detecting system 210 may be capable of determining the orientation of the object based on angle of the orientation. Preferably, a triangular based detecting system is used in this mode. As described above, the detecting system 220 is preferably an optical light based system. However, those of the art will recognize that the detecting system 220 may also be other types of systems capable of determining the orientation of the substrate. Although the disclosure refers to a light beam being used, those skilled in the art will recognize that any suitable emitted wave (such as ultrasonic, electromagnetic, of light) can be utilized. Processed wafers are generally highly optically reflective, similar to a mirror. This property is conductive to implementing an angle sensor.

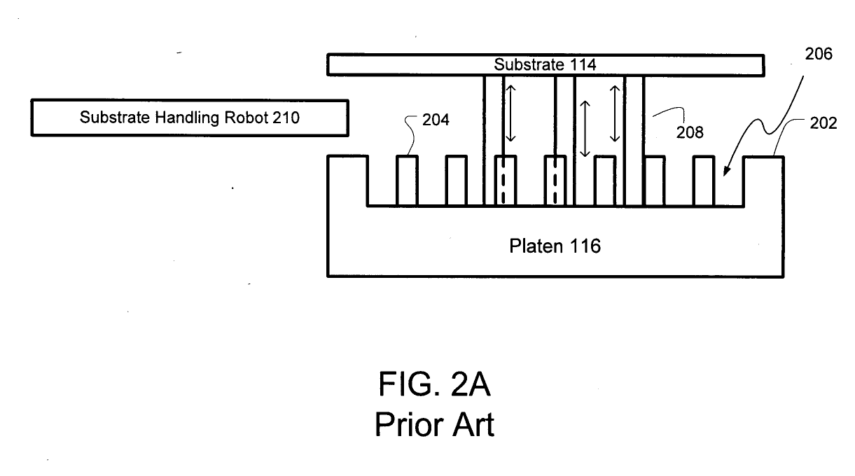

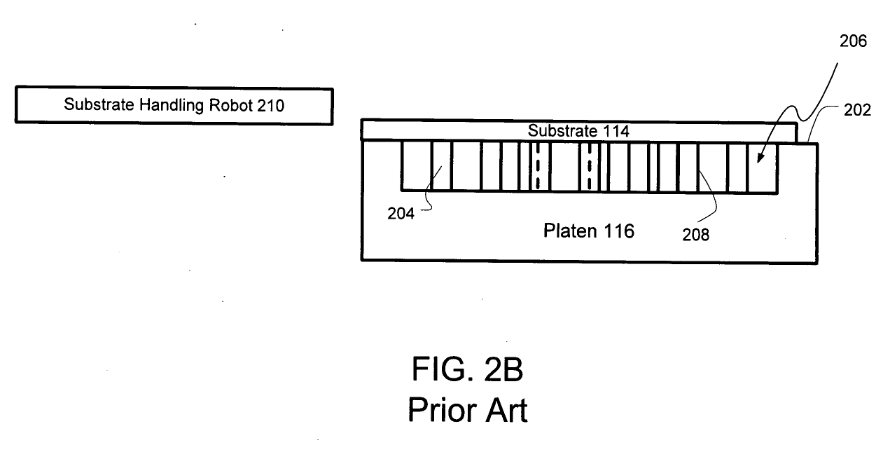

Hereinafter, operation of the angle based method for determining orientation of the substrate 114 will be described. Initially, the substrate 114 is received by the lift pins 208 of the platen 116, as shown FIG. 2A. After processing the substrate 114, the substrate may be raised to the elevated state by the lift pins 208 to be retrieved by the substrate handling robot 210.

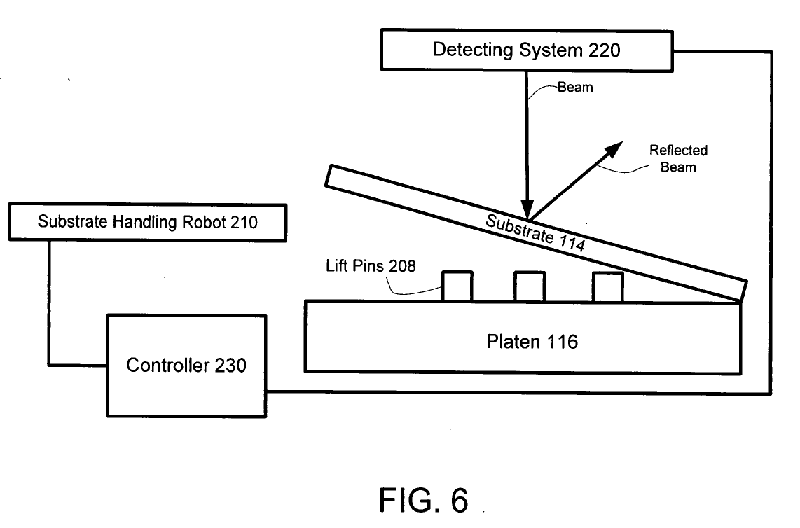

Prior to being retrieved, an electromagnetic wave, such as an optical beam, from the detecting system 220 may be directed to the substrate. In many cases, the substrate surface 114 may be highly reflective to the optical beam. FIG. 4 illustrates a scenario in which the substrate 114 has been properly lifted. In this case, the reflected beam travels back toward the detecting system 220, as the surface of the substrate is roughly orthogonal to the direction of the applied optical beam. However, if a portion of the substrate remains attached to the platen, the substrate 114 may be in the tilted state, as shown in FIG. 6. If the degree of tilt is high, the optical beam reflected by the substrate 114 may be sufficiently deflected so that it can no longer be detected by the detecting system 220. In one embodiment, the detecting system 220 is located about 1 meter from the substrate 114. In this case, a tilt of 1 degree will deflect the reflected beam by approximately 2 cm. Obviously, a larger tilt angle will deflect the reflected beam even further away from the detecting system 220, as shown in FIG. 6. In this case, the detecting system 220 may not detect, or may detect only a small amount of reflected beam. Thus, the range of acceptable tilt is determined by the width of the light sensor and the distance between the detecting system and the substrate. As the distance between the detecting system 220 and the substrate 114 decreases, the acceptable range of tilt angles increases. Thereafter, the orientation of the substrate 114 may be determined. If the light sensor receives the reflected beam, the tilt angle is within the acceptable range. However, if the light sensor receives an insufficient amount of the reflected beam, the tilt angle is outside the acceptable range. If it is determined that the substrate 114 is in an excessively tilted state, the controller 230 may prevent the substrate handling robot 210 from retrieving the substrate 114. Otherwise, the robot may retrieve the substrate.

An advantage of the angle based method may be that the method may compensate the detecting system 220 having difficulty in accurately measuring distance between the substrate 114 and the detecting system 220. Such a difficulty may arise due to the highly reflective nature of the substrate surface. In the present disclosure, the angle based method may preferably be implemented with a “line” beam rather than a spot beam, as the line beam may accurately determine the tilt state even if angular variation is in one direction.

In the present disclosure, the detecting system 220 may be oriented such that the line beam has a parallel relationship with any two lift pins. Such an orientation may allow the determination of the substrate's tilt about a line between the two lift pins. FIG. 3 illustrated these axes of tilt 209 for a platen having three lifting pins 208. Also, with this orientation, tilting about the other two axes of tilting (parallel to other two pairs of lift pins) may be detected with about half of the accuracy of tilting about the primary alignment axis.

In another embodiment, a camera, such as a CCD camera is positioned next to the platen. When the substrate is lifted by the lift pins, the camera is used to capture an image of the substrate configuration. If the image shows that the substrate is flat, and at the proper elevation relative to the platen, the substrate-handling robot is used to remove the substrate. However, if the substrate is tilted, or if the elevation relative to the platen is not within an acceptable range, the robot is prohibited from removing the substrate.

Thus, the detecting system 220 is adapted to detect a parameter related to the orientation of the substrate. In some embodiments, this parameter is the distance from the detecting system 220 to the substrate 114. In other embodiments, this parameter is the angle of substrate 114 relative to a fixed surface, such as the platen 116. Furthermore, as described above, in certain embodiments, multiple detecting systems are utilized to detect these parameters for a plurality of portions of the substrate.

Although embodiments described herein are directed to a specific apparatus and method for detecting the substrate orientation and for handling the substrate processed by ion implanter, the present disclosure may be applicable to other processing system such as, for example, PIII system, PLAD system, laser processing system. As such, the present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Further, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes.

What is claimed is:

1. A system for handling a substrate, comprising:
a detecting system, adapted to detect a parameter related to the orientation of a portion of said substrate; and
a substrate handling robot adapted to handle said substrate, in response to said orientation.

2. The system of claim 1, wherein said orientation is an orientation of said substrate relative to a fixed surface.

3. The system of claim 2, wherein said fixed surface comprises a surface of a platen.

4. The system of claim 2, wherein said substrate handling robot is prevented from handling said substrate if at least a portion of said substrate is in contact with said fixed surface.

5. The system of claim 1, further comprising a controller configured to instruct said substrate handling robot to handle said substrate having determining that said orientation is within an acceptable range.

6. The system of claim 1, wherein said detecting system comprises a distance measurement system and said parameter comprises the distance from said detecting system to said portion of said substrate.

7. The system of claim 1, wherein said detecting system comprises an angle measurement system and said parameter comprises the angle of said substrate relative to said platen.

8. The system of claim 1, wherein said detecting system is selected from the group consisting of an optical system, an induction system, an ultrasonic system, and an electromagnetic system.

9. The system of claim 1, further comprising a second detecting system, adapted to detect a parameter related to the orientation of a second portion of said substrate.

10. A method for handling a substrate, comprising:
utilizing a detecting system, adapted to detect a parameter related to the orientation of a portion of said substrate relative to said platen, a controller in communication with said detecting system, adapted to determine if said orientation is within an acceptable range, and a substrate handling robot in communication with said controller, adapted to handle said substrate;
measuring, using said detecting system, a first distance to said substrate after said robot places said substrate on lift pins of said platen;
processing said substrate;
measuring, using said detecting system, a second distance to said substrate after said substrate has been processed;
comparing said first and second distances to determine if said orientation is acceptable; and
using said robot to remove said substrate from said platen if said orientation is acceptable.

11. The method of claim 10, wherein said detecting system is selected from the group consisting of an optical system, an induction system, an ultrasonic system, and an electromagnetic system.

12. The method of claim 10, further comprising a second detecting system, adapted to detect the distance to a second portion of said substrate.

13. The method of claim 12, wherein said first and second distance measurements are performed for a plurality of portions of said substrate.

14. The method of claim 10, wherein said robot does not remove said substrate is said orientation is unacceptable.

15. A method for removing a substrate from a platen after said substrate has been processed, comprising:
utilizing a detecting system, adapted to detect a parameter related to the orientation of a portion of said substrate relative to said platen, a controller in communication with said detecting system, adapted to determine if said orientation is within an acceptable range, and a substrate handling robot in communication with said controller, adapted to handle said substrate;
positioning said detecting system a known distance from said platen;
directing a wave from said detecting system toward said substrate;
measuring a wave reflected from said substrate by said detecting system;
comparing the amplitude of said reflected wave to an acceptable range to determine if said orientation is acceptable; and
using said robot to remove said substrate from said platen if said orientation is acceptable.

16. The method of claim 15, wherein said detecting system is selected from the group consisting of an optical system, an inductive system, an ultrasonic system, and an electromagnetic system.

17. The method of claim 15, wherein said wave comprises a light beam.

18. A method for handling a substrate, comprising:
determining a parameter related to the orientation of said substrate relative to a substrate support; and
handling said substrate in response to said determined orientation.

19. The method of claim 18, wherein said determining comprises:
measuring a distance to said substrate during a first predetermined time;
measuring the distance to said substrate during a second predetermined time; and
comparing the distances.

20. The method of claim 19, wherein said determining comprises determining angle of said substrate relative to said substrate support.
